(19) United States
(12) Patent Application Publication
(10) Pub. No.: US 2009/0026462 A1
(43) Pub. Date: Jan. 29, 2009

(54) WIRING SUBSTRATE AND METHOD OF MANUFACTURING SAME, AND DISPLAY DEVICE

(75) Inventor: Takafumi HASHIGUCHI, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 12/170,783

(22) Filed: Jul. 10, 2008

(30) Foreign Application Priority Data
Jul. 24, 2007 (JP) 2007-192477

(51) Int. Cl. H01L 29/04; H01L 21/84

(52) U.S. Cl. 257/72; 438/151; 257/E29.003; 257/E21.7

(57) ABSTRACT

A wiring substrate includes a plurality of lines provided on the substrate, and a plurality of mounting terminals each for respective one of the plurality of lines, the plurality of mounting terminals being arranged in several rows in a staggered pattern, wherein the mounting terminal includes a first conductive film formed in the same layer as the lines, an insulating film covering the lines and the first conductive film, the insulating film having an opening above the first conductive film, and an upper layer conducive film electrically connected to the first conductive film through the opening, and wherein the insulating film includes a thick film portion located on the outside of the area where the plurality of mounting terminals are arranged in several rows in the staggered pattern, and a thin film portion located in the area adjacent to the opening in the row direction of the staggered pattern with a thickness thinner than the thick film portion.

### BACKGROUND OF THE INVENTION

1. Field of the Invention

The present invention relates to a wiring substrate and a method of manufacturing the same, and a display device.

2. Description of Related Art

A liquid crystal display device is thin and light, and has low power consumption, and thereby has been used as a display device for various equipments. In particular, as mobile information equipment such as a mobile phone has become smaller and thinner, COG (Chip On Glass) mounting technique has been used more widely as a mounting method of a driver IC that is used to drive a liquid crystal display device in such equipment.

In the COG mounting method, a driver IC is directly mounted on a glass substrate having mounting terminals formed on the substrate. In most cases, the driver IC is electrically connected to the mounting terminals through an ACF (Anisotropic Conductive Film) in the COG mounting (for example, see Japanese unexamined patent application publication No. 2002-229058). The ACF is an insulating thermosetting adhesive dispersed with conductive particles, which are resin balls coated with Au, Ni, or the like.

In recent year, pixel (dot) pitch has decreased to the order of 40 to 60 μm in liquid crystal display devices used for mobile information equipment, as the resolution has become higher. The distance between mounting terminals becomes so small in such narrow pitch that the mounting of a driver IC becomes very difficult. Therefore, to secure a longer pitch of mounting terminals, they are usually arranged in a staggered pattern (see Japanese unexamined patent application publication No. 2002-196703). For example, the pitch of mounting terminals can become twice as large as the wiring pitch by staggering them in two rows.

FIG. 15 is a plane view showing the arrangement of mounting terminals in a conventional liquid crystal display device. FIG. 16 shows a cross-sectional view as taken along the line XVI-XVI in FIG. 15. As shown in FIG. 15, a mounting terminal 6 is formed in each line 2a. In this example, the mounting terminals 6 are staggered in two rows. Therefore, the line 2a is located between two neighboring mounting terminals 6.

As shown in FIG. 16, the mounting terminal 6 has stacked structure. That is, a first conductive film 2, which is the same layer as the line 2a, is formed on a substrate 1. Then, an insulating film 4 having an opening 5 is stacked on the first conductive film 2. Furthermore, an upper conductive film 7 is provided such that it covers the opening 5. A projecting electrode (bump 12) made of Au or the like is formed on the driver IC 11. In COG mounting, this bump 12 is aligned with the opening 5 of the mounting terminal 6 and bonded together by thermocompression. In this manner, the driver IC 11 is electrically connected to the mounting terminal 6 through the conductive particles 14 of the ACF 13.

However, due to the narrower pitch designs in recent years, the pitch L of the mounting terminals 6 has become very narrow, i.e., in the order of 30 to 40 μm even in the staggered arrangement shown in FIGS. 15 and 16. As a result, the first conductive film 2 needs to be reduced in width in the design of the mounting terminals 6. Therefore, the opening 5, which is provided for the electrical connection to the driver IC 11, also needs to be reduced in width. As a result, improvements in the alignment accuracy between the bumps 12 and the openings 5 in the width direction of the mounting terminals 6 have been desired in COG mounting. In other words, the tolerance range on the alignment accuracy in the width direction of the mounting terminals 6 has become increasingly smaller.

In the conventional liquid crystal display device shown in FIGS. 15 and 16, the insulating film 4 is composed of insulating films 4a, 4b, and 4c. That is, it has stacked structure in which an insulating film 4a made of a gate insulating film or the like, an insulating film 4b made of an interlayer insulating film or the like that is provided over the TFT, and an insulating film 4c made of an organic film or the like on which a concavity and convexity pattern is formed are stacked one after another. Consequently, as shown in FIG. 16, a step d is formed between the opening 5 of the mounting terminal 6 and the area located between neighboring mounting terminals 6. Therefore, if the alignment is not carried out within the tolerance range on the alignment accuracy, the bump 12 partially sits on the insulating film 4 and does not fall into the opening 5. Accordingly, the following problems occur.

In the case where the mounting is carried out through the ACF 13 as with the example shown in FIGS. 15 and 16, the area where the bump 12 and mounting terminal 6 overlap decreases, and thereby the number of conductive particles 14 that contribute to the electrical connection is reduced. As a result, the occurrence of continuity failure increases. Furthermore, since the bump 12 does not fall into the opening 5, the conductive particles 14 located within the opening 5 are not properly squashed, and thereby sufficient pressure bonding cannot be achieved. Therefore, even if the proper continuity is achieved immediately after the mounting, continuity failure may occur during use, and thereby it poses a problem in reliability.

Furthermore, in the case where the bump 12 directly contacts with the mounting terminal 6 without the ACF 13 in the mounting, only part of the upper conductive film 7 that is located in the periphery of the opening 5 on the insulating film 4 contacts with the bump 12. Therefore, the area where the bump 12 and the mounting terminal 6 contact with each other significantly decreases. As a result, electrical resistance between the bump 12 and the mounting terminal 6 increases, and continuity failure may occur.

In one aspect, the present invention has been made to solve the above-described problems. One of the objects of the present invention is to provide a wiring substrate capable of increasing the tolerance range on the alignment accuracy in the mounting of an external circuit to mounting terminals and a method of manufacturing the same, and a display device.

### SUMMARY OF THE INVENTION

In accordance with one example of the present invention, a wiring substrate includes: a plurality of lines provided on a substrate; and a plurality of mounting terminals each corresponding to respective one of the plurality of lines, the plurality of mounting terminals being arranged in several rows in a staggered pattern, wherein the mounting terminal includes: a first conductive film formed in the same layer as the lines; an insulating film covering the lines and the first conductive film, the insulating film having an opening above the first conductive film; and an upper layer conducive film electrically connected to the first conductive film through the opening, and wherein the insulating film includes: a thick film portion located on the outside of the area where the plurality of mounting terminals are arranged in several rows in the staggered pattern; and a thin film portion located in the areas adjacent to the openings in the row direction of the staggered pattern with a thickness thinner than the thick film portion.

Furthermore, in accordance with another example of the present invention, a method of manufacturing a wiring substrate having a plurality of lines, and a plurality of mounting terminals each corresponding to respective one of the plurality of lines, the plurality of mounting terminals being arranged in several rows in a staggered pattern, includes: forming the lines and a first conductive film of the mounting terminals over a substrate; forming an insulating film that covers the line and the first conductive film and has an opening above the first conductive film; and forming an upper layer conducive film electrically connected to the first conductive film through the opening, and wherein in the forming of the insulating film, both a thick film portion located on the outside of the area where the plurality of mounting terminals are arranged in several rows in the staggered pattern, and a thin film portion located in the area adjacent to the opening in the row direction of the staggered pattern with a thickness thinner than the thick film portion, are formed in the insulating film.

In accordance with one aspect, the present invention can provide a wiring substrate capable of increasing the tolerance range on the alignment accuracy in the mounting of an external circuit to mounting terminals and a method of manufacturing the same, and a display device.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a front view showing the structure of a TFT array substrate in accordance with a first embodiment of the present invention;

FIG. 2 is a plane view showing the structure of mounting terminals of a liquid crystal display device in accordance with the first embodiment of the present invention;

FIG. 3 is a cross-sectional view as taken along the line III-III in FIG. 2;

FIGS. 4A to 4E are cross-sectional views showing a manufacturing process of a wiring substrate in accordance with the first embodiment of the present invention;

FIG. 5 is a plane view showing the structure of mounting terminals of a liquid crystal display device in accordance with a second embodiment of the present invention;

FIG. 6 is a cross-sectional view as taken along the line VI-VI in FIG. 5;

FIGS. 7A to 7E are cross-sectional views showing a manufacturing process of a wiring substrate in accordance with the second embodiment of the present invention;

FIG. 8 is a plane view showing the structure of mounting terminals of a liquid crystal display device in accordance with a third embodiment of the present invention;

FIG. 9 is a cross-sectional view as taken along the line IX-IX in FIG. 8;

FIGS. 10A to 10E are cross-sectional views showing a manufacturing process of a wiring substrate in accordance with the third embodiment of the present invention;

FIG. 11 is a plane view showing the structure of mounting terminals of a liquid crystal display device in accordance with a fourth embodiment of the present invention;

FIG. 12 is a cross-sectional view as taken along the line XII-XII in FIG. 11;

FIG. 13 is a plane view showing the structure of mounting terminals of a liquid crystal display device in accordance with a fifth embodiment of the present invention;

FIG. 14 is a cross-sectional view as taken along the line XIV-XIV in FIG. 13;

FIG. 15 is a plane view showing the structure of mounting terminals of a conventional liquid crystal display device; and

FIG. 16 is a cross-sectional view as taken along the line XVI-XVI in FIG. 15.

### DESCRIPTION OF THE PREFERRED EMBODIMENTS

### First Embodiment

Firstly, a display device in accordance with one example of the present invention is explained hereinafter with reference to FIG. 1. FIG. 1 is a front view showing the structure of a TFT array substrate for use in a display device. While a liquid crystal display device is explained as an example of the display device in the following embodiments, the explanation is made only for the illustrative purpose. For example, other flat-panel display devices, such as an organic electroluminescence display device can be used as a substitute for the liquid crystal display device. The overall structures of the liquid crystal display devices are substantially the same throughout the following first to fifth embodiments.

A liquid crystal display device in accordance with one example of the present invention has a substrate 1. The substrate 1 is, for example, an array substrate such as a TFT array substrate. A display area 41 and a frame area 42 surrounding the display area 41 are provided on the substrate 1. A plurality of gate lines (scanning signal lines) 43 and a plurality of source lines (display signal lines) 44 are formed in the display area 41. The plurality of gate lines 43 are arranged in parallel with each other. Similarly, the plurality of source lines 44 are arranged in parallel with each other. The gate line 43 and source line 44 are formed such that they intersect with each other. The gate line 43 and source line 44 intersect at right angles with each other. The area defined by adjacent gate lines 43 and source lines 44 becomes a pixel 47. Consequently, the pixels 47 are arranged in matrix in the substrate 1.

A scanning signal drive circuit 45 and a display signal drive circuit 46 are provided in the frame area 42 of the substrate 1. The gate line 43 extends from the display area 41 into the frame area 42, and connects to the scanning signal drive circuit 45 at the edge portion of the substrate 1. Similarly, the source line 44 extends from the display area 41 into the frame area 42, and connects to the display signal drive circuit 46 at the edge portion of the substrate 1. An external wiring 48 is connected near the scanning signal drive circuit 45. Furthermore, an external wiring 49 is connected near the display signal drive circuit 46. The external wirings 48 and 49 are, for example, wiring boards such as FPCs (Flexible Printed Circuits).

Various external signals are supplied to the scanning signal drive circuit 45 and the display signal drive circuit 46 through the external wirings 48 and 49. The scanning signal drive circuit 45 supplies a gate signal (scanning signal) to the gate line 43 based on the external control signal. The gate lines 43 are sequentially selected by this gate signal. The display signal drive circuit 46 supplies a source signal to the source line 44 based on the external control signal, or external display data. In this manner, display voltage corresponding to the display data can be supplied to the pixel 47.

At least one TFT 50 is formed in the pixel 47. The TFT 50 is located near the intersection of the source line 44 and the gate line 43. For example, the TFT 50 supplies a display voltage to a pixel electrode. That is, the TFT 50, which is a switching element, is turned on by a gate signal from the gate line 43. In this manner, the display voltage is applied from the source line 44 to the pixel electrode that is connected to a drain electrode of the TFT 50. An electric field corresponding to the display voltage is produced between the pixel electrode and an opposed electrode. Incidentally, an alignment layer (not shown) is formed on the surface of the substrate 1.

Furthermore, an opposed substrate is arranged opposite to the substrate 1. The opposed substrate is, for example, a color filter substrate, and located at the viewing side of the substrate 1. A color filter, a black matrix (BM), an opposed electrode, an alignment layer, and the like are formed on the opposed substrate. Incidentally, the opposed electrode may be located on the substrate 1 rather than on the opposed substrate. A liquid crystal layer is sandwiched between the substrate 1 and the opposed substrate. That is, liquid crystal is filled between the substrate 1 and the opposed substrate. Furthermore, a polarizing plate, a retardation film, and the like are provided on the outer surfaces of the substrate 1 and the opposed substrate. Furthermore, a backlight unit or the like is provided at the non-viewing side of the liquid crystal display panel.

The liquid crystal is driven by the electric field between the pixel electrode and the opposed electrode. That is, it changes the alignment direction of the liquid crystal located between the substrates. With this change, the polarization state of light passing through the liquid crystal layer changes. That is, light which passes through the polarization plate becomes linearly polarized light, and it further changes its polarization state by passing through the liquid crystal layer. Specifically, light from the backlight unit becomes linearly polarized light by the polarizing plate located on the array substrate side. As the linearly polarized light passes through the liquid crystal layer, its polarization state changes.

The amount of the light that passes through the polarizing plate located on the opposed substrate side varies depending on the polarization state. That is, the amount of the light that passes through the polarizing plate at the viewing side, out of the transmitted light that is transmitted from the backlight unit to the liquid crystal display panel, varies. The alignment direction of the liquid crystal varies depending on the applied display voltage. Therefore, the amount of the light that passes through the polarizing plate at the viewing side can be varied by controlling the display voltage. That is, a desired image can be displayed by varying the display voltages on a pixel-by-pixel basis.

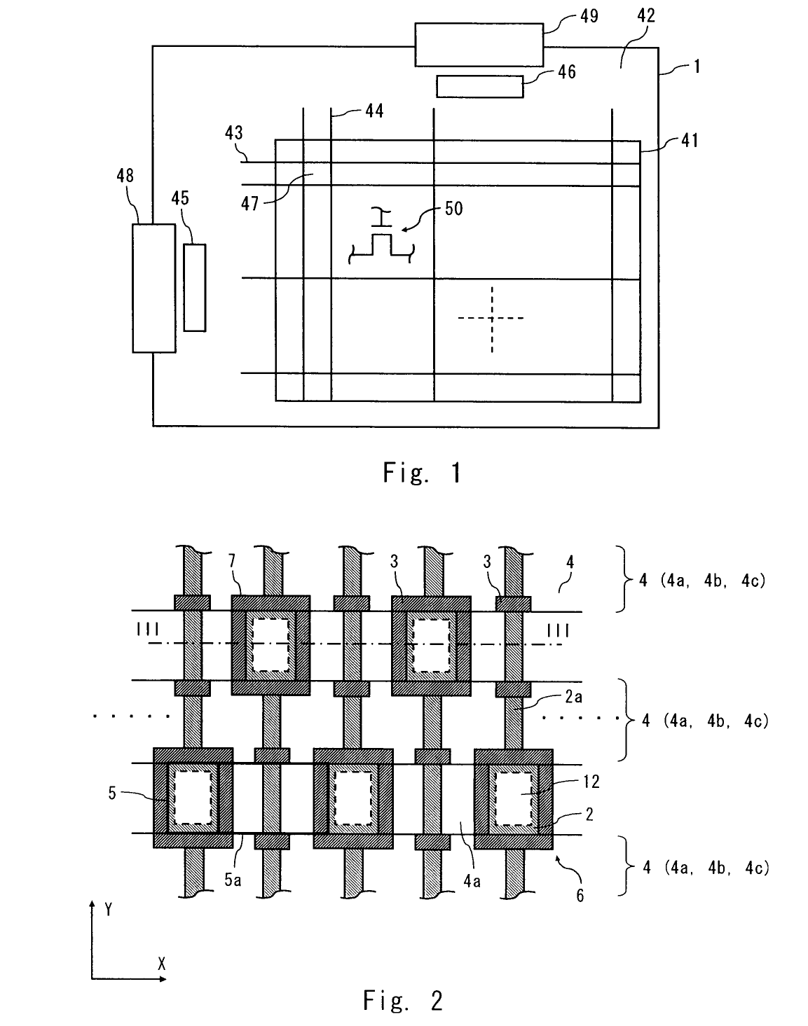

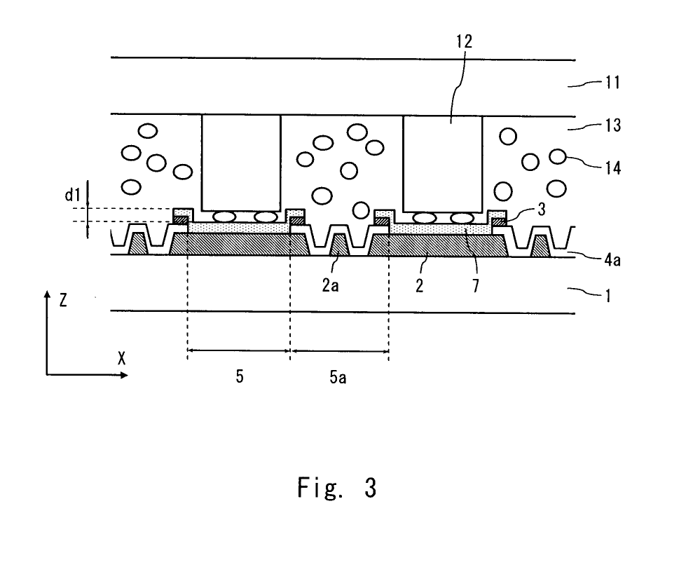

Next, the structure of a mounting terminal in accordance with this embodiment is explained in detail with reference to FIGS. 2 and 3. FIG. 2 is a plane view showing the structure of mounting terminals of a liquid crystal display device in accordance with the first embodiment of the present invention. FIG. 3 is a cross-sectional view as taken along the line III-III in FIG. 2. A mounting terminal 6 in accordance with this embodiment is provided, for example, in the lead-out line of the gate line 43 extending to the frame area 42 shown in FIG. 1, and formed near the connection to the scanning signal drive circuit 45. The mounting terminal 6 in accordance with this embodiment is also formed, for example, in the lead-out line of the source line 44 near the connection to the display signal drive circuit 46.

In FIG. 2, a plurality of lines 2a extending in the Y-direction are formed. The plurality of lines 2a are arranged in parallel in the X-direction. In the following explanation, X-direction is defined as the row direction of mounting terminals, and Y-direction is defined as the direction orthogonal to the X-direction. The line 2a is, for example, the lead-out line of the gate line 43 or the source line 44 shown in FIG. 1. A mounting terminal 6 is provided in the line 2a to make an electrical connection to a driver IC 11. The driver IC 11 is, for example, the scanning signal drive circuit 45 or the display signal drive circuit 46 shown in FIG. 1. To accommodate a narrow pitch, the mounting terminals 6 are arranged in a staggered pattern as shown in FIG. 2. That is, the mounting terminals 6 in adjacent lines 2a are not arranged in the X-direction, but arranged in several rows that are arranged in the Y-direction. In this embodiment, the staggered pattern of two rows is illustrated as an example, in which the mounting terminals 6 are arranged in two rows that are arranged in the Y-direction. Therefore, neighboring lines 2a are arranged alternately with neighboring mounting terminals 6 in the X-direction.

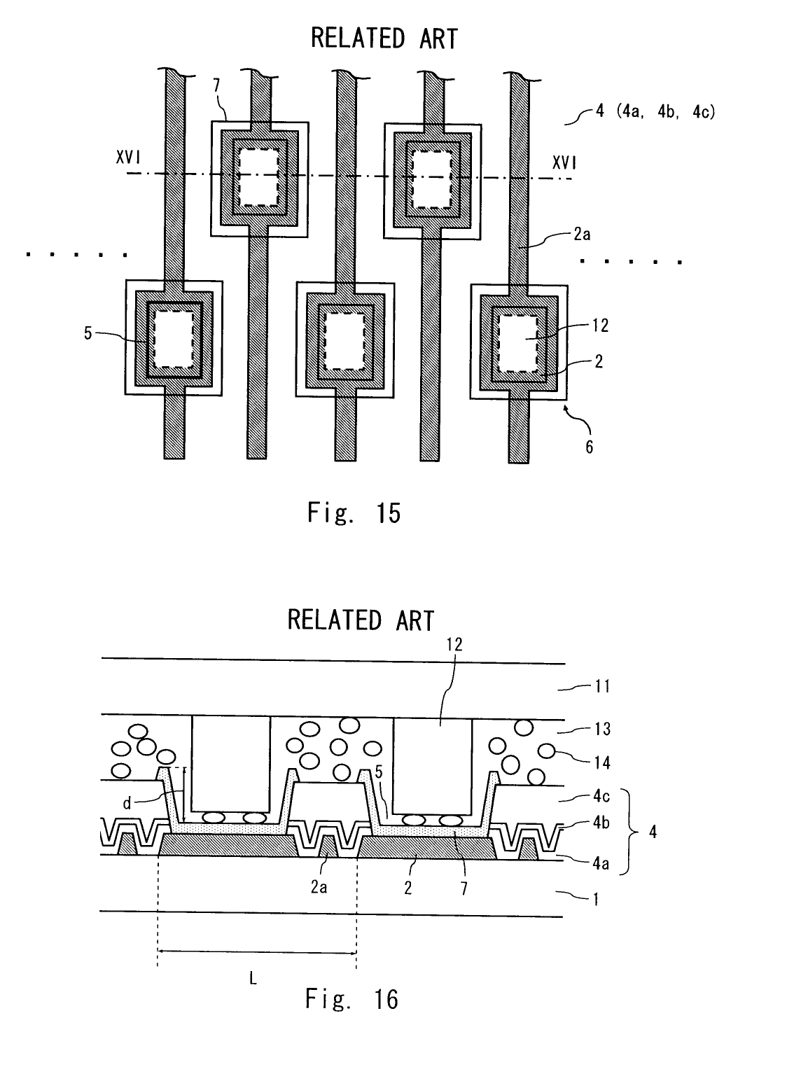

Furthermore, as shown in FIG. 3, a first conductive film 2 is formed in the same layer as the lines 2a on the substrate 1. The line 2a and the first conductive film 2 are formed from a metal film such as an Al film. For example, the first conductive film 2 can be formed from the same layer as one of the gate line 43 and the source line 44. An insulation film 4 is provided such that it covers the line 2a and the first conductive film 2. Similarly to the conventional liquid crystal display shown in FIG. 16, the insulating film 4 is composed of insulating films 4a, 4b, and 4c. That is, it has stacked structure in which an insulating film 4a made of a gate insulating film of the TFT 50 or the like (first insulating film), an insulating film 4b made of an interlayer insulating film or the like that is provided over the TFT 50 (second insulating film), and an insulating film 4c made of a organic film or the like on which a concavity and convexity pattern is formed (third insulating film) are stacked one after another. The insulating films 4a and 4b are formed, for example, from inorganic films such as silicon dioxide films or silicon nitride films.

In this embodiment of the present invention, an opening 5 and a thin film portion 5a are formed in the insulating film 4. That is, the thin film portion 5a in which the insulating films 4b and 4c are removed, and the opening 5 in which the insulating films 4a, 4b, and 4c are removed are formed in the insulating film 4. Similarly to the conventional liquid crystal display device shown in FIG. 16, the opening 5 is formed above the first conductive film 2. The size of the opening 5 is smaller than that of the first conductive film 2, and the opening 5 is placed such that any part of the opening 5 does not stick out from the patterned area of the first conductive film 2. Furthermore, the thin film portion 5a is formed on the area adjacent to the opening 5 in the X-direction. More specifically, the thin film portion 5a is formed above the line 2a in the area adjacent to the mounting terminal 6 such that the thin film portion 5a adjoins the opening 5. Therefore, the thin film portion 5a is formed between the neighboring openings 5 in the X-direction. Accordingly, in the insulating film 4, the area having the insulating film 4a alone (thin film portion 5a) is formed outside of the opening 5 in the X-direction, and the area having the insulating films 4a, 4b, and 4c (thick film portion) is formed outside of the opening 5 in the Y-direction. The insulating film 4 prevents a short circuit and erosion of the line 2a. That is, the line 2a is covered by the insulating films 4a, 4b, and 4c in the thick film portion. Furthermore, the line 2a is covered by the insulating film 4a in the thin film portion 5a.

Incidentally, a second conductive film 3 is provided on the insulating film 4a in a frame shape such that it surrounds the opening 5 in this embodiment. The second conductive film 3 is formed from a metal film such as an Al film. For example, the second conductive film 3 can be formed from the same layer as the other of the gate line 43 and the source line 44. The second conductive film 3 is arranged such that the edge on the opening 5, i.e., the inner edge of the second conductive film 3 is located at generally the same position as the outer shape of the opening 5. The outer edge of the second conductive film 3 is located, for example, on the inside of the patterned edge of the first conductive film 2.

Furthermore, an upper conductive layer 7 is formed on the insulating film 4 such that it covers the opening 5. For example, the upper conductive film 7 has a shape smaller than the first conductive film 2, and is formed such that the outer edge of the upper conductive film 7 is located at generally the same place as the patterned outer edge of the second conductive film 3. That is, the second conductive film 3 is located between the upper conductive film 7 and the insulating film 4a in the area peripheral to the opening 5 in the X-direction. Meanwhile, the upper conductive film 7 overlaps with the second conductive film 3 with the insulating films 4b and 4c interposed therebetween in the area peripheral to the opening 5 in the Y-direction. The upper conductive film 7 is electrically connected to the first conductive film 2 through the opening 5. The upper conductive film 7 is formed from conductive oxide film such as ITO. For example, the upper conductive film 7 is formed from a transparent conductive film in the same layer as the pixel electrode that is provided within the pixel 47.

In this manner, the first conductive film 2 and the upper conductive film 7 are stacked in the listed order in the area within the opening 5 in the mounting terminal 6 in accordance with this embodiment. In the peripheral edge of the mounting terminal 6, the first conductive film 2, the insulating film 4a, the second conductive film 3, and the upper conductive film 7 are stacked on the substrate 1 in the area on the outside of the opening 5 in the X-direction. In the peripheral edge of the mounting terminal 6, the first conductive film 2, the insulating film 4a, the insulating film 4b, the insulating film 4c, the second conductive film 3, and the upper conductive film 7 are stacked on the substrate 1 in the area on the outside of the opening 5 in the Y-direction. Furthermore, the insulating film 4a is stacked such that it covers the line 2a in the area adjacent to the mounting terminal 6 in the X-direction.

A driver IC 11 is mounted to the mounting terminals 6 having such structure by COG mounting technique, and electrically connected to the mounting terminals 6 through an ACF (Anisotropic Conductive Film) 13. Specifically, the ACF 13 is an insulating thermosetting adhesive dispersed with conductive particles 14, which are resin balls coated with Au or Ni. The driver IC 11 has bumps 12 in the area that faces the openings 5. The bump 12 is formed from Au or the like. In COG mounting, this bump 12 is aligned with the opening 5 of the mounting terminal 6 and bonded together by thermocompression. In this manner, the driver IC 11 is electrically connected to the mounting terminals 6 through the conductive particles 14 of the ACF 13.

Assume a case where a certain shifting in the X-direction in the alignment (shifting of the mounting position in the X-direction) occurs, so that the bump 12 does not fall into the opening 5 and partially sits on the insulating film 4a during the COG mounting. The height of the step d1 between the opening 5 and the area on the outside of the opening 5 in the X-direction in the peripheral edge of the mounting terminal 6 is in the order of the 0.5 μm in this embodiment of the present invention. This value of the step d1 is significantly lower than that of the step d in the structure in the related art. Therefore, considering that the diameter of the conductive particle 14 is 3 to 4 μm, the bump 12 and the mounting terminal 6 can contact with each other without causing any problem regardless of the presence of the step d1. Furthermore, the line 2a is covered by the insulating film 4a. Therefore, even if part of the bump 12 is placed directly above the line 2a owing to the shifting of the mounting position in the X-direction, the bump 12 does not cause a short circuit with the line 2a.

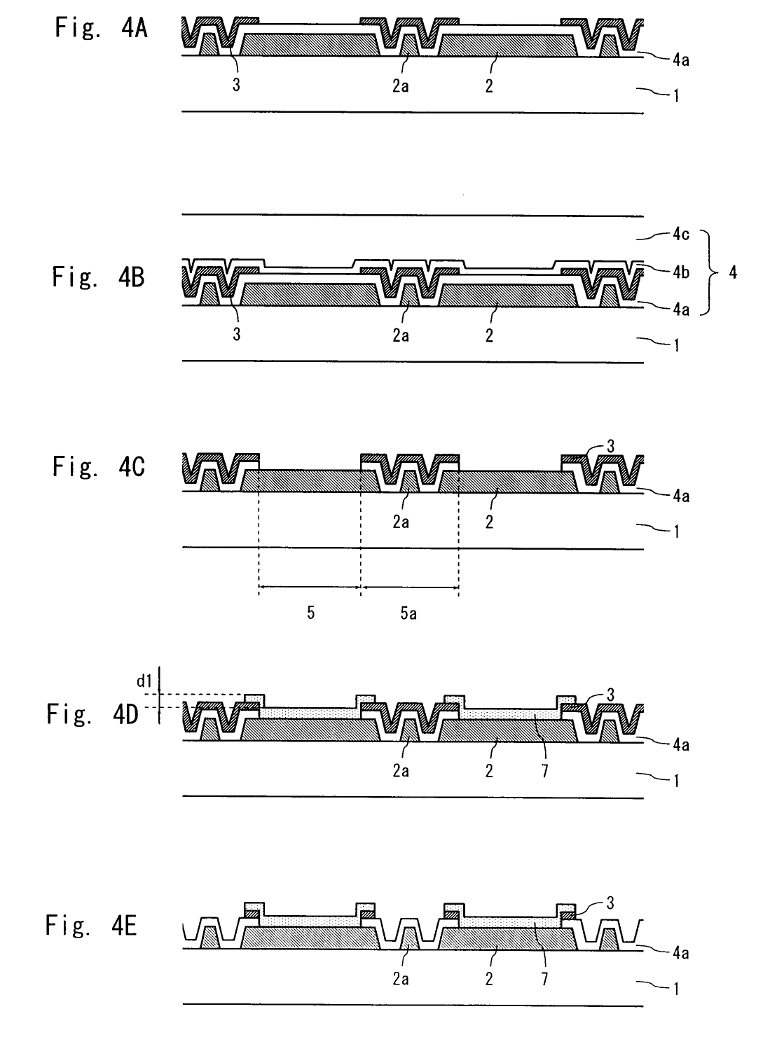

Next, a method of manufacturing mounting terminals in accordance with this embodiment is explained in detail hereinafter with reference to FIGS. 4A to 4E. FIGS. 4A to 4E are cross-sectional views showing a manufacturing process of a wiring substrate in accordance with the first embodiment of the present invention. Similarly to FIG. 3, FIGS. 4A to 4E show cross-sectional views as taken along the line III-III in FIG. 2.

Firstly, a first conductive film 2 is deposited on the entire surface of the substrate 1 by sputtering or a similar method. A metal film such as an Al film can be used for the first conductive film 2. A resist is patterned on the first conductive film 2 by photolithography or a similar method. The first conductive film 2 is etched using this resist pattern as a mask in order to form lines 2a and a first conductive film 2 for the mounting terminals 6. At this point, the first conductive film 2 can be formed without increasing the number of processes by forming it, for example, by the same layer as one of the gate line 43 and the source line 44.

Next, an insulating layer 4a is deposited on the entire surface of the substrate 1 by plasma CVD or a similar method. An inorganic film such as a silicon nitride film is used for the insulating film 4a. Furthermore, the insulating film 4a can be formed without increasing the number of processes by forming it, for example, by the same layer as the gate insulating film of the TFT 50. In this manner, the line 2a and the first conductive film 2 for the mounting terminal 6 is covered by the insulating film 4a. The semiconductor layer of the TFT 50 is formed after the deposition of the insulating film 4a. Incidentally, the semiconductor layer is formed in the display area 41, and is not formed in the vicinity of the mounting terminal shown in FIG. 2 in this embodiment.

Then, a second conductive film 3 is deposited on the entire surface of the substrate 1 by sputtering or a similar method. The second conductive film 3 can be formed from a metal film such as an Al film. Then, a resist pattern is formed on the second conductive film 3 by photolithography or a similar method. The second conductive film 3 is etched to a desired pattern using this resist pattern as a mask. In this manner, as shown in FIG. 4A, the pattern of the second conductive film 3 is formed on part of the line 2a and the mounting terminal 6. Specifically, the pattern of the second conductive film 3 is formed on the entire area over the first conductive film 2 except for the area that is to be the opening 5. The second conductive film 3 is also formed in the area covering the line 2a in the area adjacent to the first conductive film 2 of the mounting terminal 6 in the X-direction. The second conductive film 3 is also formed in the area that is to be the thin film portion 5a. At this point, the second conductive film 3 can be formed without increasing the number of processes by forming it, for example, by the same layer as the other of the gate line 43 and the source line 44.

Next, an insulating layer 4b is deposited on the entire surface of the substrate 1 by plasma CVD or a similar method such that the insulating layer 4b covers the second conductive film 3. An inorganic film such as a silicon nitride film can be used for the insulating film 4b. Furthermore, an insulating film 4c composed of an organic film or the like is coated on the insulating film 4b. In this manner, it has structure shown in FIG. 4B. At this point, the number of processes can remain unchanged if the insulating film 4b is formed by the same layer as the interlayer insulating film and the insulating film 4c is formed by the same layer as the organic film that is used to form the concavity and convexity pattern in the pixel 47.

The insulating film 4c is patterned by photolithography or a similar method after the coating of the insulating film 4c. In this manner, the insulating film 4c is removed and the insulating film 4b is exposed in the area that is to be the opening 5 and the thin film portion 5a. Furthermore, the area where the insulating film 4c remains is to be the thick film portion of the insulating film 4. The insulating film 4b and the insulating film 4a are removed together by carrying out dry etching or a similar method using this insulating film 4c as a mask. At this point, the second conductive film 3 acts as an etching stopper in the area that is to be the thin film portion 5a. Therefore, the insulating film 4b, which is located above the second conductive film 3, is removed, and the insulating film 4a, which is located below the second conductive film 3, is not removed in the thin film portion 5a. In this manner, as shown in FIG. 4C, the opening 5 and the thin film portion 5a are formed simultaneously in the insulating film 4. At this point, the opening 5 and the thin film portion 5a can be formed without increasing the number of necessary masks if the patterning of the insulating film 4c is carried out in the same process as the formation of the contact hole in the pixel 47.

An upper conductive film 7 is deposited on the entire surface of the substrate 1 by sputtering or a similar method after the formation of the opening 5 and the thin film portion 5a in the insulating film 4. A conductive oxide film having transparency such as ITO can be used for the upper conductive film 7. Then, the upper conductive film 7 is patterned through photolithography, etching, and resist-removal processes. In this manner, as shown in FIG. 4D, the opening 5 is covered by the upper conductive film 7. At this point, the upper conductive film 7 can be formed without increasing the number of processes by forming it, for example, by the same layer as the pixel electrode in the display area 41.

At this stage, neighboring mounting terminals 6 are being electrically connected with each other through the second conductive film 3. Therefore, the second conductive film 3 is removed such that the neighboring mounting terminals 6 are electrically isolated from each other. In this example, the second conductive film 3 is patterned by wet etching or a similar method using the upper conductive film 7 formed in the step shown in FIG. 4D as a mask. In this manner, as shown in FIG. 4E, the second conductive film 3 that is exposed on the surface is removed. That is, among the entire second conductive film 3 that is formed in the thin film portion 5a, only the second conductive film 3 that is not covered by the upper conductive film 7 is removed. Incidentally, among the second conductive film 3 that is formed in the area covering the line 2a in the area adjacent to the first conductive film 2 of the mounting terminal 6 in the X-direction, the second conductive film 3 located in the area that overlaps with the insulating film 4c is not removed, and remains as a patterned shape that straddles the line 2a. The wiring substrate having the mounting terminals 6 formed on the substrate in accordance with this embodiment is completed through these processes.

After the wiring substrate that is manufactured in this manner and an opposed substrate such as a color filter are stuck together with a sealing material, liquid crystal is filled into the gap between the substrates. Furthermore, a component to be mounted such as a driver IC 11 is mounted on the wiring substrate. COG mounting technique can be used to mount the driver IC 11 on the wiring substrate. The bumps 12 of the driver IC 11 are aligned with the openings 5 of the mounting terminals 6 such that they face each other, and bonded together by thermocompression. In this manner, the driver IC 11 is electrically connected to the mounting terminals 6 through the ACF 13. The liquid crystal display device in accordance with this embodiment is completed in this manner.

As explained above, the second conductive film 3 is formed on the insulating film 4a that covers the lines 2a and the first conductive film 2 of the mounting terminals 6 in this embodiment. At this point, the second conductive film 3 is formed in the area above the first conductive film 2 except for the area for the opening 5, the area covering the lines 2a in the area adjacent to the first conductive film 2 in the X-direction, and the area that is to be the thin film portion 5a. In this manner, while the openings 5 piercing through the insulating films 4a, 4b, and 4c are formed, the thin film portions 5a where the insulating films 4b and 4c are removed can be formed by using the second conductive film 3 as an etching stopper. In addition, neighboring mounting terminals 6 can be electrically isolated by removing the second conductive film 3 using the upper conductive film 7 as a mask. With such method, the step d1 between the opening 5 and the area on the outside of the opening 5 in the X-direction becomes significantly lower than the step d in the related art shown in FIG. 16. Accordingly, even if part of the bump 12 is placed above the insulating film 4a or the line 2a owing to the shifting of the mounting position in the X-direction, the bump 12 does not cause a short circuit with the line 2a, and the bump 12 can securely contact with the mounting terminal 6. Therefore, the display device having the mounting terminals 6 formed on the substrate in accordance with this embodiment can improve the reliability. The mounting terminal 6 having such structure can increase the tolerance range on the alignment accuracy in the mounting of a driver IC.

### Second Embodiment

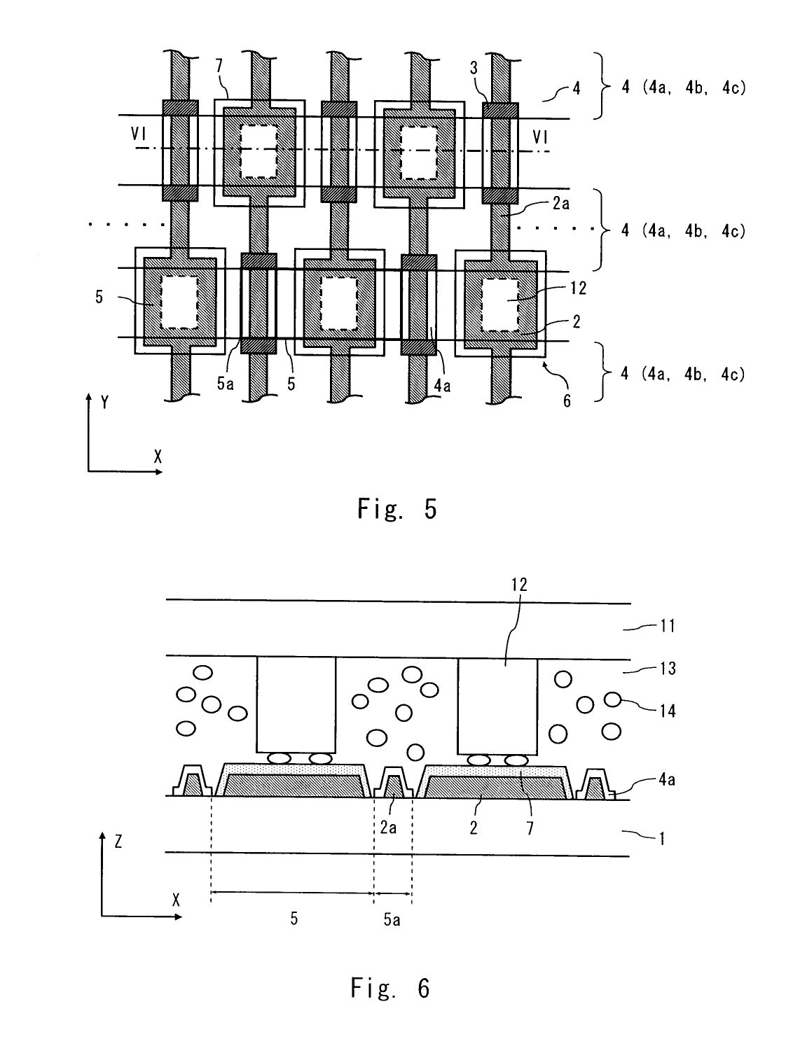

The structure of a mounting terminal in accordance with a second embodiment is explained in detail hereinafter with reference to FIGS. 5 and 6. FIG. 5 is a plane view showing the structure of mounting terminals of a liquid crystal display device in accordance with a second embodiment of the present invention. FIG. 6 is a cross-sectional view as taken along the line VI-VI in FIG. 5. This embodiment is different from the first embodiment in the structure of the mounting terminals. However, other structures are the same as the first embodiment, and therefore explanation of the other structures is omitted.

In FIGS. 5 and 6, the same signs are assigned to the potions having structures similar to those of FIGS. 2 and 3, and differences are explained. In FIG. 5, similarly to the first embodiment, mounting terminals 6 are arranged in several rows in a staggered pattern to accommodate a narrow pitch. In this embodiment, the staggered pattern of two rows is illustrated as an example in which the mounting terminals 6 are arranged in two rows arranged in the Y-direction. Therefore, neighboring lines 2a are arranged alternately with neighboring mounting terminals 6 in the X-direction.

In FIG. 6, similarly to the first embodiment, a first conductive film 2 is formed in the same layer as the lines 2a on the substrate 1. An insulating film 4, which is composed of insulating films 4a, 4b, and 4c, is provided such that it covers the lines 2a and the first conductive film 2. Thin film portions 5a in which the insulating films 4b and 4c are removed, and openings 5 piercing through the insulating films 4a, 4b, and 4c are formed in the insulating film 4.

In this embodiment, the areas where the opening 5 and thin film portion 5a are formed are different from those of the first embodiment. That is, the opening 5 has a larger width in the X-direction than that of the first embodiment, and is formed with a wider width than the first conductive film 2. Then, the thin film portion 5a is formed in the areas adjacent to the opening 5 in the X-direction. Therefore, the thin film portion 5a is formed between the neighboring openings 5 in the X-direction. The thin film portion 5a has a smaller width in the X-direction than that of the first embodiment, and is formed such that it straddles the line 2a in the area adjacent to the opening 5. Similarly to the first embodiment, the area having the insulating film 4a alone is formed on the outside of the opening 5 in the X-direction in the insulating film 4, and the area having the insulating films 4a, 4b, and 4c is formed on the outside of the opening 5 in the Y-direction in the insulating film 4. The insulating film 4 prevents a short circuit and erosion of the lines 2a. That is, the line 2a is covered by the insulating films 4a, 4b, and 4c, or covered by the insulating film 4a in the area where the line 2a overlaps with the thin film portion 5a.

Furthermore, an upper conductive film 7 is provided on the insulating film 4 such that it covers the first conductive film 2 in this embodiment. That is, the upper conductive film 7 is lager in size than the first conductive film 2, and arranged such that any part of the first conductive film 2 does not stick out from the upper conductive film 7. Furthermore, the upper conductive film 7 is also arranged such that the pattern of the upper conductive film 7 is separated away from the outer edge of the thin film portion 5a. The upper conductive film 7 is electrically connected to the first conductive film 2 through the opening 5. Incidentally, the second conductive film 3 surrounding the opening 5 in a frame shape in the first embodiment shown in FIG. 2 is not formed in this embodiment.

In this manner, the first conductive film 2 and the upper conductive film 7 are stacked in the listed order in the areas within the opening 5 in the mounting terminal 6 in accordance with this embodiment. Furthermore the insulating film 4a is stacked such that it covers the lines 2a in the areas adjacent to the mounting terminal 6 in the X-direction.

Similarly to the first embodiment, a driver IC 11 is mounted to the mounting terminals 6 having such structure through the ACF 13 by COG mounting technique. At this point, even if a certain shifting of the mounting position in the X-direction occurs during the COG mounting, there is substantially no difference in height between the area above the mounting terminal 6 in the opening 5 and the adjacent area between the mounting terminals 6 in the X-direction. Therefore, the bump 12 and mounting terminal 6 can contact with each other without causing any problem. Furthermore, the line 2a is covered by the insulating film 4a. Therefore, even if part of the bump 12 is placed directly above the line 2a owing to the shifting of the mounting position in the X-direction, the bump 12 does not cause a short circuit with the line 2a.

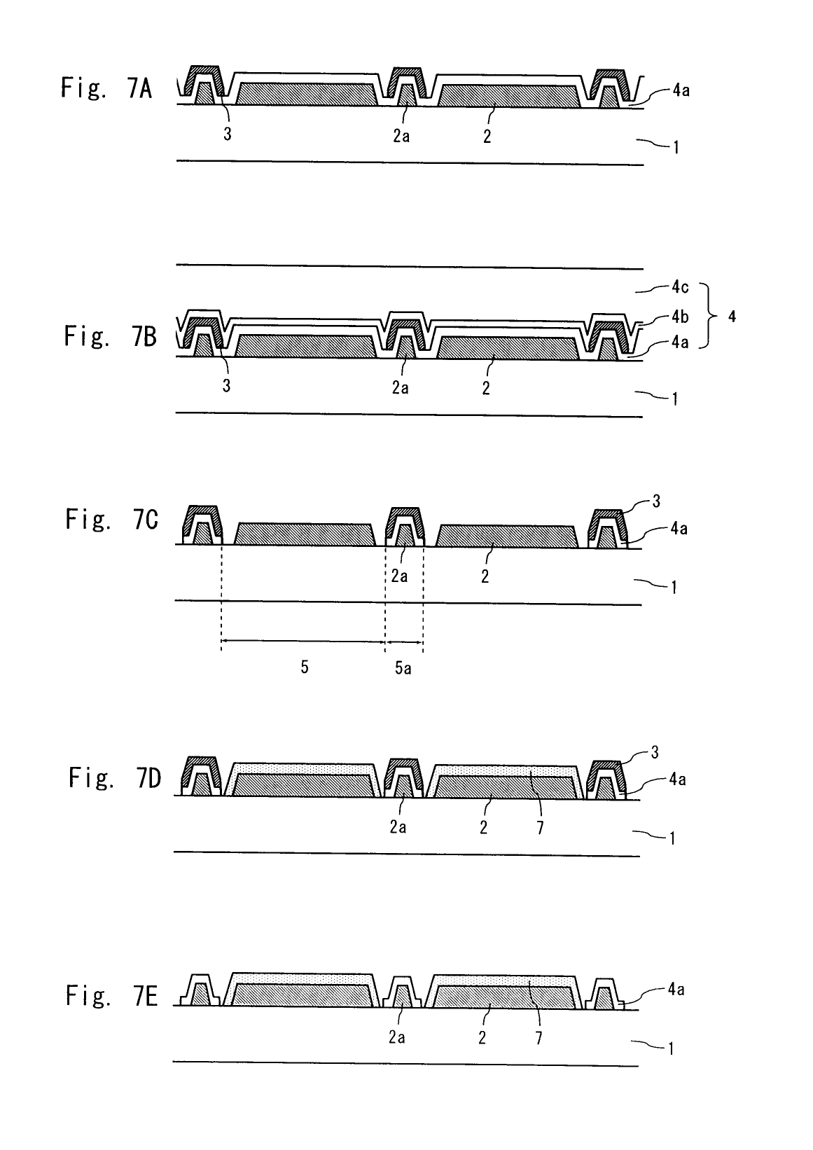

A method of manufacturing mounting terminals in accordance with this embodiment is explained in detail hereinafter with reference to FIGS. 7A to 7E. FIGS. 7A to 7E are cross-sectional views showing a manufacturing process of a wiring substrate in accordance with the second embodiment of the present invention. Similarly to FIG. 6, FIGS. 7A to 7E show cross-sectional views as taken along the line VI-VI in FIG. 5.

For the mounting terminal 6 in accordance with this embodiment, the second conductive film 3 having a different shape from that of the first embodiment is formed after the formation of the insulating film 4a, which covers the line 2a and the second conductive film 3 formed on the substrate 1. In this manner, as shown in FIG. 7A, the pattern of a second conductive film 3 is formed above part of the line 2a. Specifically, the pattern of the second conductive film 3 is formed in the area above the line 2a including the area that is to be the thin film portion 5a. Furthermore, the second conductive film 3 is patterned such that its width in the X-direction is larger than that of the line 2a, and its length in the Y-direction is also larger, for example, than that of the first conductive film 2.

Next, similarly to the first embodiment, after an insulating film 4b is deposited on the entire surface of the substrate 1, an insulating film 4c is coated so as to form the structure shown in FIG. 7B. Then, similarly to the first embodiment, the insulating film 4c is patterned and the insulating film 4c in the area that is to be the opening 5 and the thin film portion 5a is removed. The insulating film 4b and the insulating film 4a are removed together by carrying out dry etching or a similar method using the pattern of the insulating film 4c as a mask. At this point, similarly to the first embodiment, the second conductive film 3 acts as an etching stopper in the area that is to be the thin film portion 5a. Therefore, the insulating film 4b, which is located above the second conductive film 3, is removed, and the insulating film 4a, which is located below the second conductive film 3, is not removed in the thin film portion 5a. In this manner, as shown in FIG. 7C, the opening 5 and the thin film portion 5a are formed in the insulating film 4.

Next, similarly to the first embodiment, an upper conductive film 7 is deposited on the entire surface of the substrate 1. Then, the upper conductive film 7 is patterned through photolithography, etching, and resist-removal processes. The upper conductive film 7 having a shape larger than the first conductive film 2 of the mounting terminal 6 is formed in this embodiment. In this manner, as shown in FIG. 7D, the first conductive film 2 is covered by the upper conductive film 7.

At this stage, the second conductive film 3 is exposed in the thin film portion 5a. Therefore, if the shifting of the mounting position in the X-direction occurs, neighboring mounting terminals are electrically connected with each other through the second conductive film 3. Accordingly, the second conductive film 3 is removed by wet etching or a similar method such that the second conductive film 3 is not exposed on the surface. In this example, since the upper conductive film 7 formed in the step shown in FIG. 7D acts as a mask, only the second conductive film 3 that is exposed in the thin film portion 5a is removed. In this manner, as shown in FIG. 7E, the second conductive film 3 that is exposed on the surface is removed. Incidentally, similarly to the first embodiment, the second conductive film 3 in the area that overlaps with the insulating film 4c is not removed, and remains as a patterned shape that straddles the line 2a. The wiring substrate having the mounting terminals 6 formed on the substrate in accordance with this embodiment is completed through these processes.

As explained above, the second conductive film 3 is formed on the insulating film 4a that covers the lines 2a. At this point, the second conductive film 3 is formed in the area above the lines 2a including the area that is to be the thin film portion 5a. In this manner, the following advantageous effects as well as the advantageous effects of the first embodiment are obtained. That is, this embodiment does not have the structure in which the upper conductive film 7 is stacked directly on the second conductive film 3. Therefore, it can prevent the second conductive film 3 from being etched inwardly beyond the edge of the upper conductive film 7 to the extent that it becomes a protrusion during the process in which the second conductive film 3 is removed by wet etching or a similar method after the formation of the upper conductive film 7. Consequently, it can prevent the occurrence of failure and defectiveness such as a short circuit of neighboring mounting terminals 6 owning to the peeling of the upper conductive film 7 at the protrusion.

### Third Embodiment

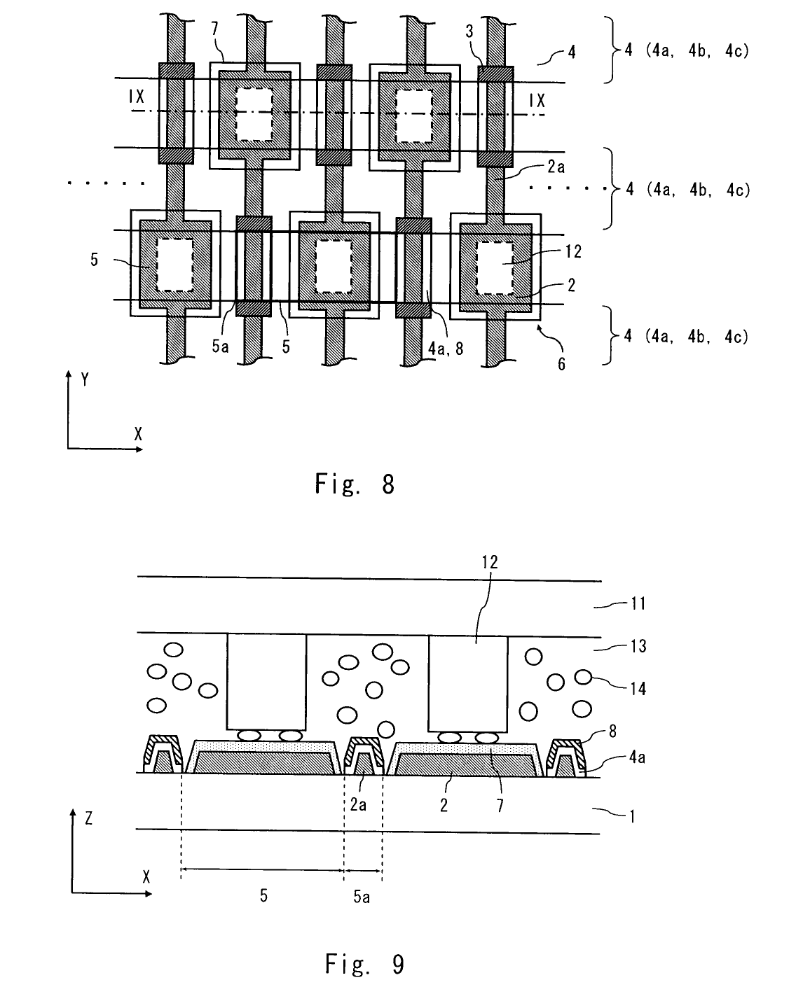

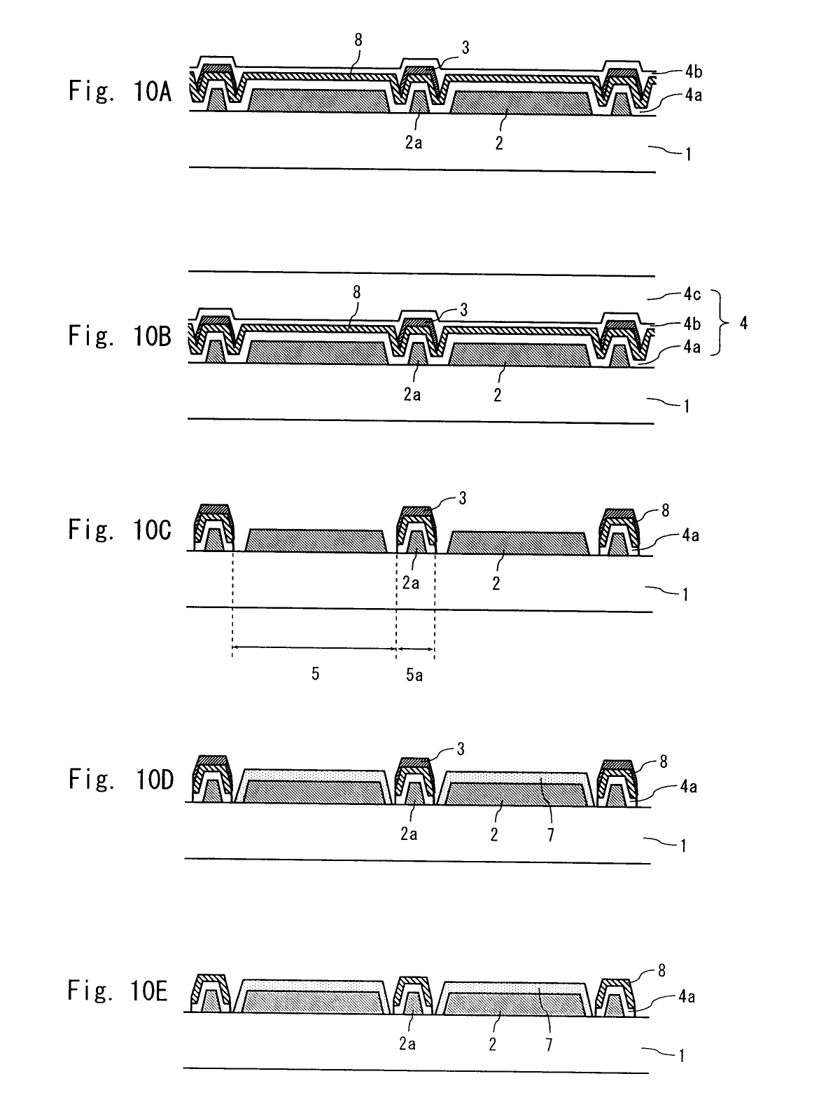

The structure of a mounting terminal in accordance with a third embodiment is explained in detail hereinafter with reference to FIGS. 8 and 9. FIG. 8 is a plane view showing the structure of mounting terminals of a liquid crystal display device in accordance with a third embodiment of the present invention. FIG. 9 is a cross-sectional view as taken along the line IX-IX in FIG. 8. In this embodiment, the line 2a is further covered by a semiconductor layer in the thin film portion 5a. However, other structures are the same as the second embodiment, and therefore explanation of the other structures is omitted.

In FIGS. 8 and 9, the same signs are assigned to the potions having structures similar to those of FIGS. 5 and 6, and differences are explained. In FIGS. 8 and 9, similarly to the second embodiment, a line 2a is provided in the thin film portion 5a on the substrate 1, and an insulating film 4a is formed to cover the line 2a. In this embodiment, a semiconductor layer 8 is also stacked on the insulating film 4a. Incidentally, the semiconductor layer 8 may be formed in other areas, as well as in the thin film portion 5a, except for the area for the opening 5. In such case, the semiconductor layer 8 is arranged between the insulating film 4a and the second conductive film 3 or the insulating film 4b.

Similarly to the first and second embodiments, a driver IC 11 is mounted to the mounting terminals 6 having such structure through the ACF 13 by COG mounting technique. At this point, even if a certain shifting of the mounting position in the X-direction occurs during the COG mounting, there is substantially no difference in height between the area above the mounting terminal 6 in the opening 5 and the adjacent area between the mounting terminals 6 in the X-direction. Therefore, the bump 12 and the mounting terminal 6 can contact with each other without causing any problem. Furthermore, the line 2a is covered by the insulating film 4a. Therefore, even if part of the bump 12 is placed directly above the line 2a owing to the shifting of the mounting position in the X-direction, the bump 12 does not cause a short circuit with the line 2a.

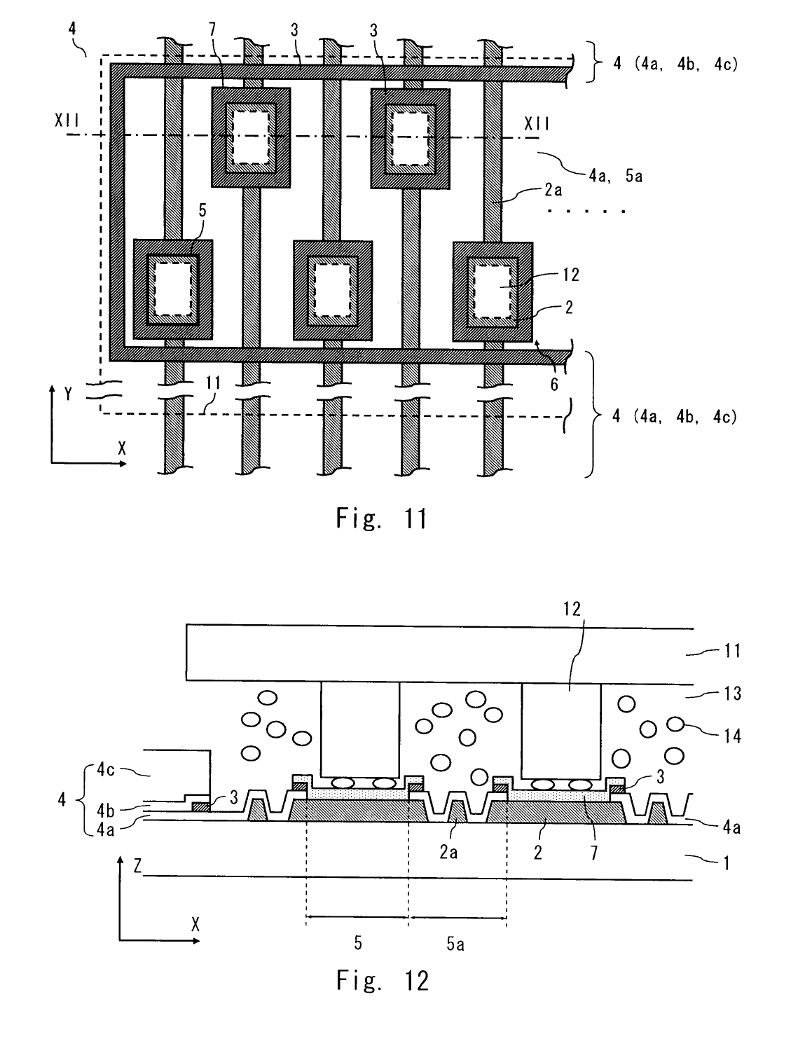

A method of manufacturing mounting terminals in accordance with this embodiment is explained in detail hereinafter with reference to FIGS. 10A to 10E. FIGS. 10A to 10E are cross-sectional views showing a manufacturing process of a wiring substrate in accordance with the third embodiment of the present invention. Similarly to FIG. 9, FIGS. 10A to 10E show cross-sectional views as taken along the line IX-IX in FIG. 8.

For the mounting terminal 6 in accordance with this embodiment, a semiconductor layer 8 is deposited on the entire surface of the substrate 1 after the formation of the insulating film 4a, which covers the line 2a and the second conductive film 3 formed on the substrate 1. The semiconductor layer 8 can be formed by the same layer as the semiconductor layer of the TFT 50. Then, a second conductive film 3 having the same shape as that of the second embodiment is formed on the semiconductor layer 8. In this manner, as shown in FIG. 10A, the pattern of a second conductive film 3 is formed above part of the line 2a.

Next, similarly to the second embodiment, after an insulating film 4b is deposited on the entire surface of the substrate 1, an insulating film 4c is coated so as to form the structure shown in FIG. 10B. Then, similarly to the second embodiment, the insulating film 4c is patterned and the insulating film 4c in the area that is to be the opening 5 and the thin film portion 5a is removed. The insulating film 4b, the semiconductor layer 8, and the insulating film 4c are removed together by carrying out dry etching or a similar method using the pattern of the insulating film 4c as a mask. At this point, similarly to the second embodiment, the second conductive film 3 acts as an etching stopper in the area that is to be the thin film portion 5a. Therefore, the insulating film 4b, which is located above the second conductive film 3, is removed, and the insulating film 4a and the semiconductor layer 8, both of which are located below the second conductive film 3, are not removed in the thin film portion 5a. In this manner, as shown in FIG. 10C, the opening 5 and the thin film portion 5a are formed in the insulating film 4.

Next, similarly to the second embodiment, an upper conductive film 7 is deposited on the entire surface of the substrate 1. Then, the upper conductive film 7 is patterned through photolithography, etching, and resist-removal processes. In this manner, as shown in FIG. 10D, the first conductive film 2 is covered by the upper conductive film 7.

Then, similarly to the second embodiment, the second conductive film 3 is removed by wet etching or a similar method. In this example, since the upper conductive film 7 formed in the step shown in FIG. 10D acts as a mask, only the second conductive film 3 that is exposed in the thin film portion 5a is removed. In this manner, as shown in FIG. 10E, the second conductive film 3 that is exposed on the surface is removed, and the semiconductor layer 8 is exposed in the thin film portion 5a. The wiring substrate having the mounting terminals 6 formed on the substrate in accordance with this embodiment is completed through these processes.

As explained above, the second conductive film 3 is formed after the semiconductor layer 8 is stacked on the insulating film 4a in this embodiment. In this manner, the following advantageous effects as well as the advantageous effects of the second embodiment are obtained. That is, the line 2a in the area adjacent to the mounting terminal 6 is covered by the stacked layer of the insulating film 4a and the semiconductor layer 8 in this embodiment. Consequently, higher resistance to erosion can be obtained for the line 2a, and therefore the reliability of the mounting terminal 6 in accordance with this embodiment is improved.

### Fourth Embodiment

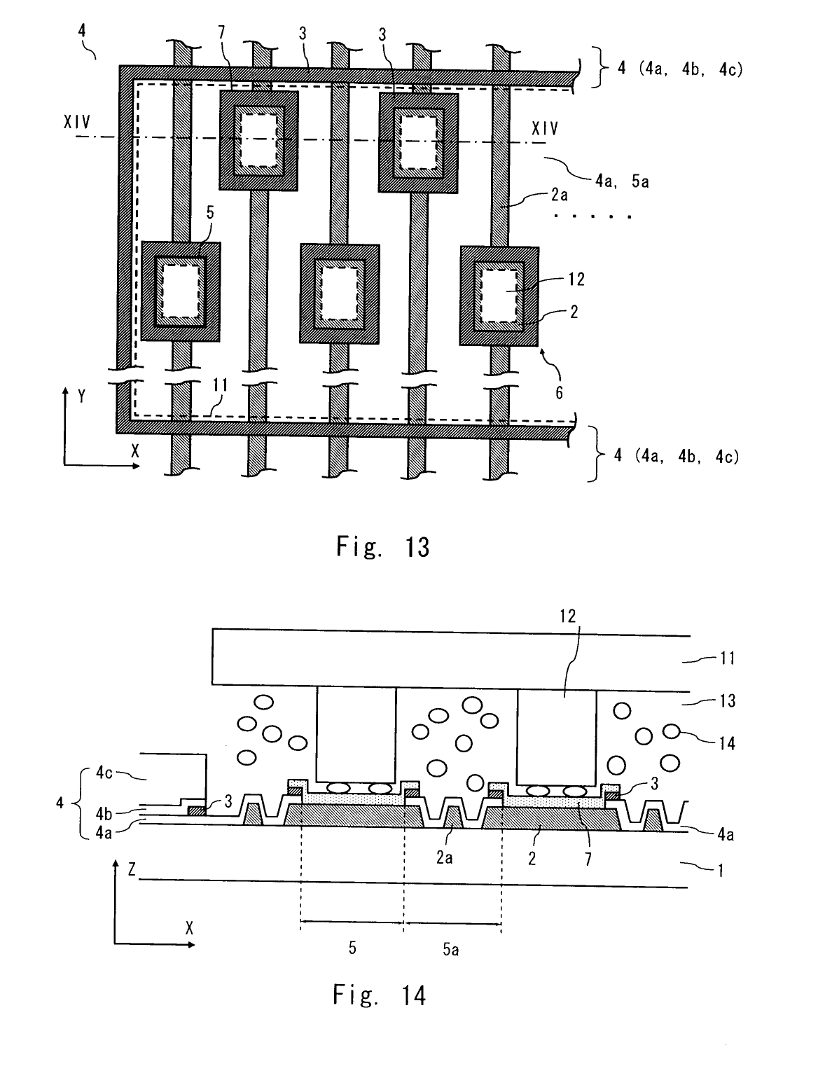

The structure of mounting terminals in accordance with a forth embodiment is explained in detail hereinafter with reference to FIGS. 11 and 12. FIG. 11 is a plane view showing the structure of mounting terminals of a liquid crystal display device in accordance with a fourth embodiment of the present invention. FIG. 12 is a cross-sectional view as taken along the line XII-XII in FIG. 11. This embodiment is different from the first embodiment in the structure of the mounting terminals. However, other structures are the same as the first embodiment, and therefore explanation of the other structures is omitted. Incidentally, FIGS. 11 and 12 show part of the area, where a plurality of mounting terminals 6 are arranged in a staggered pattern, including the end portion of the area.

In FIGS. 11 and 12, the same signs are assigned to the potions having structures similar to those of FIGS. 2 and 3, and differences are explained. Similarly to the first embodiment, an opening 5, a thin film portion 5a having a insulating film 4a alone, and a thick film portion having insulating films 4a, 4b, and 4c are formed in the insulating film 4. In this embodiment, the area where the thin film portion 5a is formed is different from that of the first embodiment. That is, the area where the thin film portion 5a is formed is larger than that of the first embodiment.

As shown in FIGS. 11 and 12, the thin film portion 5a is formed throughout the entire area where a plurality of mounting terminals 6 are arranged in several rows in a staggered pattern except for the area where the openings 5 are formed. Then, the thick film portion is formed on the outside of the area where the plurality of mounting terminals 6 are arranged. Although the thick film portion is formed in the area between mounting terminals that correspond to neighboring lines in the first embodiment shown in FIG. 2, such thick portion is not formed in this embodiment. Therefore, the thin film portion 5a is formed with sufficiently large length and width in both X-direction and the Y-direction to contain a plurality of openings 5, and the thick film potion is formed such that it surrounds the thin film portion 5a. Incidentally, a second conductive film 3 that surrounds the thin film portion 5a in a frame shape, as well as the second conductive film 3 that surrounds the opening 5, is provided on the insulating film 4a in this embodiment.

Similarly to the first embodiment, a driver IC 11 is mounted to the mounting terminals 6 having such structure through the ACF 13 by COG mounting technique. At this point, the driver IC 11 is preferably aligned with the substrate 1 such that the peripheral edge of the driver IC 11 overlaps with the thick portion of the insulating film 4. That is, the size of the thin film portion 5a is preferably determined such that the entire thin film portion 5a is located within the outer shape of the driver IC 11. In this example, the step between the area within the opening 5 above the mounting terminal 6 and the area on the outside of the opening 5 in the Y-direction is significantly lower than the step of the first embodiment. Therefore, similarly to the case of the shifting of the X-direction, even if a certain shifting of the mounting position in the Y-direction occurs during the COG mounting, the bump 12 and the mounting terminal 6 can contact with each other without causing any problem. Furthermore, the line 2a is covered by the insulating film 4a. Therefore, even if part of the bump 12 is placed directly above the line 2a, the bump 12 does not cause a short circuit with the line 2a.

Next, a method of manufacturing mounting terminals in accordance with this embodiment is explained hereinafter. The second conductive film 3 is patterned into different places from those of the first embodiment. Manufacturing processes other than that are fundamentally the same as those of the first embodiment shown in FIGS. 4A to 4E, and explanation of them is omitted. In FIG. 4A, similarly to the first embodiment, after the second conductive film 3 is deposited on the insulating film 4a, etching is carried out using a resist pattern as a mask. At this point, the second conductive film 3 is patterned to a shape such that the patterned second conductive film 3 includes the area that is to be the thin film portion 5a. In this manner, the second conductive film 3 is patterned such that the second conductive film 3 remains in the entire area where the first conductive film 2 for a plurality of mounting terminals 6 is arranged in a staggered pattern, except for the area for the openings 5.

Then, similarly to the first embodiment, an insulating film 4b is deposited such that it covers the second conductive film 3, and an insulating film 4c is coated. The insulating film 4c is patterned by photolithography, and the insulating film 4c in the areas that is to be the opening 5 and the thin film portion 5a is removed. In this embodiment, since the area where the thin film portion 5a is formed is different from that of the first embodiment, the shape of the insulating film 4c that remains after the patterning is also different from the first embodiment. That is, the insulating film 4c is formed in a shape such that it surrounds the second conductive film 3. In contrast to the first embodiment, the insulating film 4c is not formed in the area above the mounting terminals 6. At this point, the insulating film 4c is preferably formed such that the second conductive film 3 overlaps with the peripheral edge of the patterned insulating film 4c. That is, the edge of the patterned second conductive film 3 is preferably covered by the insulating film 4c on the entire periphery.

The insulating film 4b and the insulating film 4a are removed together using the pattern of the insulating film 4c as a mask. In this manner, while the opening 5 are formed in the insulating film 4, the thin film portion 5a is formed using the second conductive film 3 as an etching stopper. Next, an upper conductive film 7 is formed such that it covers the openings 5. Then, the upper conductive film 7 is used as a mask, and the exposed second conductive film 3 is removed by etching. The wiring substrate having the mounting terminals 6 formed on the substrate in accordance with this embodiment is completed through these processes.

The wiring substrate that is manufactured in this manner and an opposed substrate are stuck together, and liquid crystal is filled into the gap between the substrates. Then, a component to be mounted such as a driver IC 11 is mounted on the wiring substrate. The bumps 12 of the driver IC 11 are aligned with the openings 5 of the mounting terminals 6 such that they face each other, and bonded together by thermocompression. At this point, the driver IC 11 is preferably aligned with the substrate 1 such that the peripheral edge of the driver IC 11 overlaps with the thick portion of the insulating film 4. The liquid crystal display device in accordance with this embodiment is completed in this manner.

As explained above, the second conductive film 3 is formed on the insulating film 4a that covers the lines 2a and the first conductive film 2 of the mounting terminals 6 in this embodiment. At this point, the second conductive film 3 is patterned such that the patterned second conductive film 3 includes the area that is to be the thin film portion 5a. That is, the second conductive film 3 is formed in the entire area where the mounting terminals 6 are arranged in a staggered pattern, except for the area for the openings 5. In this manner, while the openings 5 piercing through the insulating films 4a, 4b, and 4c are formed, the thin film portion 5a where the insulating films 4b and 4c are removed can be formed by using the second conductive film 3 as an etching stopper. In addition, neighboring mounting terminals 6 can be electrically isolated by removing the second conductive film 3 using the upper conductive film 7 as a mask. With such method, the step between the opening 5 and the area on the outside of the opening 5 in the Y-direction becomes significantly lower than the step of the first embodiment. That is, the step becomes significantly lower in both X-direction and Y-direction compared to the step in the related art shown in FIG. 16. Accordingly, even if part of the bump 12 is placed above the insulating film 4a or the line 2a owing to the shifting of the mounting position in both X-direction and Y-direction, the bump 12 does not cause a short circuit with the line 2a, and therefore the bump 12 can securely contact with the mounting terminal 6. Therefore, the display device having the mounting terminals 6 formed on the substrate in accordance with this embodiment can have improved reliability. The mounting terminal 6 having such structure can increase the tolerance range on the alignment accuracy in the mounting of a driver IC.

### Fifth Embodiment

The structure of a mounting terminal in accordance with a fifth embodiment is explained in detail hereinafter with reference to FIGS. 13 and 14. FIG. 13 is a plane view showing the structure of mounting terminals of a liquid crystal display device in accordance with a fifth embodiment of the present invention. FIG. 14 is a cross-sectional view as taken along the line XIV-XIV in FIG. 13. This embodiment is different from the fourth embodiment in the structure of the mounting terminals. However, other structures are the same as the fourth embodiment, and therefore explanation of the other structures is omitted. Incidentally, FIGS. 13 and 14 show part of the area, where a plurality of mounting terminals 6 are arranged in a staggered pattern, including the end portion of the area.

In FIGS. 13 and 14, the same signs are assigned to the potions having structures similar to those of FIGS. 11 and 12, and differences are explained. Similarly to the fourth embodiment, an opening 5, a thin film portion 5a having a insulating film 4a alone, and a thick film portion having insulating films 4a, 4b, and 4c are formed in the insulating film 4. In this embodiment, the area where the thin film portion 5a is formed is different from that of the fourth embodiment. That is, the area where the thin film portion 5a is formed is larger than that of the fourth embodiment.

As shown in FIGS. 13 and 14, the thin film portion 5a is formed in the area that faces with a driver IC 11, except for the area where the openings 5 are formed. Then, the thick film portion is formed on the outside of the area that faces with the driver IC 11. Although the thick film portion is formed on the outside of the area, where a plurality of mounting terminals 6 are arranged in several rows in a staggered pattern, within the area that faces with the driver IC 11 in the fourth embodiment shown in FIG. 11, such thick portion is not formed in this embodiment. Therefore, the thin film portion 5a is formed in a larger area than that of the fourth embodiment, and the thick film potion is formed such that it surrounds this thin film portion 5a. Incidentally, similarly to the fourth embodiment, a second conductive film 3 that surrounds the thin film portion 5a in a frame shape, as well as the second conductive film 3 that surrounds the opening 5, is formed on the insulating film 4a in this embodiment.

Similarly to the fourth embodiment, a driver IC 11 is mounted to the mounting terminals 6 having such structure through the ACF 13 by COG mounting technique. At this point, the driver IC 11 is preferably aligned with the substrate 1 such that the peripheral edge of the insulating film 4 is located within the thin film portion 5a. That is, the size of the thin film portion 5a is preferably determined such that the thick film portion is located on the outside of the outer shape of the driver IC 11. Similarly to the fourth embodiment, the step between the area within the opening 5 above the mounting terminal 6 and the area on the outside of the opening 5 in the Y-direction is significantly lower than the step of the first embodiment in this example. Therefore, even if a certain shifting of the mounting position in the Y-direction as well as the X-direction occurs during the COG mounting, the bump 12 and mounting terminal 6 can contact with each other without causing any problem. Furthermore, the line 2a is covered by the insulating film 4a. Therefore, even if part of the bump 12 is placed directly above the line 2a, the bump 12 does not cause a short circuit with the line 2a.

Next, a method of manufacturing mounting terminals in accordance with this embodiment is explained hereinafter. In this embodiment, the second conductive film 3 is formed in a larger area that that of the fourth embodiment. The second conductive film 3 is patterned such that the second conductive film 3 remains in the entire area that faces with the driver IC 11, except for the area for the openings 5. Manufacturing processes other than that are fundamentally the same as those of the fourth embodiment, and explanation of them is omitted.

The wiring substrate that is manufactured in this manner and an opposed substrate are stuck together, and liquid crystal is filled into the gap between the substrates. Then, a component to be mounted such as a driver IC 11 is mounted on the wiring substrate. The bumps 12 of the driver IC 11 are aligned with the openings 5 of the mounting terminals 6 such that they face each other, and bonded together by thermocompression. At this point, the driver IC 11 is preferably aligned with the substrate 1 such that the driver IC 11 does not overlaps with the thick portion of the insulating film 4. In this manner, the boundary line between the thick film portion and the thin film portion 5a is located on the outside of the outer shape of the driver IC 11. The liquid crystal display device in accordance with this embodiment is completed in this manner.

As explained above, the second conductive film 3 is formed on the insulating film 4a that covers the lines 2a and the first conductive film 2 of the mounting terminals 6 in this embodiment. At this point, the second conductive film 3 is patterned such that the patterned second conductive film 3 includes the area that is to be the thin film portion 5a. The second conductive film 3 is formed in the entire area that faces with the driver IC 11, except for the area for the openings 5. In this manner, while the openings 5 piercing through the insulating films 4a, 4b, and 4c are formed, the thin film portion 5a where the insulating films 4b and 4c are removed can be formed by using the second conductive film 3 as an etching stopper. In addition, neighboring mounting terminals 6 can be electrically isolated by removing the second conductive film 3 using the upper conductive film 7 as a mask. With such method, the step between the opening 5 and the area on the outside of the opening 5 in the Y-direction becomes substantially as low as the step of the fourth embodiment. That is, the step becomes significantly lower in both X-direction and Y-direction compared to the step in the related art shown in FIG. 16. Accordingly, even if part of the bump 12 is placed above the insulating film 4a or the line 2a owing to the shifting of the mounting position in both X-direction and Y-direction, the bump 12 does not cause a short circuit with the line 2a, and therefore the bump 12 can securely contact with the mounting terminal 6. Therefore, the display device having the mounting terminals 6 formed on the substrate in accordance with this embodiment can improve the reliability. The mounting terminal 6 having such structure can increase the tolerance range on the alignment accuracy in the mounting of a driver IC.

Incidentally, although the thick film portion that are provided in the entire area between mounting terminals that correspond to neighboring lines in the first embodiment is formed as part of the thin film portion in the fourth and fifth embodiments, the present invention is not limited to such structure. For example, in the case where distance between the mounting terminals in the Y-direction, or distance between the mounting terminals that correspond to neighboring lines is sufficiently long, the thick film portion may be partially formed in the space. Furthermore, although the invention in accordance with the fourth and fifth embodiments is explained in combination with the first embodiment, it can be combined with the second or third embodiment.

Although embodiments where COG mounting is used are illustrated as examples in the above explanation, the present invention can be applied to other mounting techniques where an external component having bump structure such as a wiring substrate, a film substrate, and tape is mounted. Furthermore, a wiring substrate having the mounting terminal structure in accordance with one example of the present invention can be applied to a semiconductor device, an electronic circuit substrate, and the like.

Incidentally, although the mounting terminals are arranged in a staggered pattern of two rows in the first to fifth embodiments, they may be arranged in a staggered pattern of more than two rows. Furthermore, although the embodiments are illustrated with an active matrix liquid crystal display device having a TFT array substrate, the present invention is not limited to those embodiments. For example, other display devices such as an organic electroluminescence display device and an electrochromic display device can be used as a substitute for the liquid crystal display device. Furthermore, the present invention can be also applied to a display device using colloidal particles or ultrafine particles as material for display, such as electronic paper.

The above explanation has been made only for the illustrative purpose, and the present invention is not limited to the embodiments explained above. Further, components in the above-explained embodiments could be easily modified, added, and transformed by those skilled in the art without departing from the spirit and scope of the present invention.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A wiring substrate comprising:
a plurality of lines provided on a substrate; and
a plurality of mounting terminals each corresponding to respective one of the plurality of lines, the plurality of mounting terminals being arranged in several rows in a staggered pattern,
wherein the mounting terminal includes: a first conductive film formed in the same layer as the lines;
an insulating film covering the lines and the first conductive film, the insulating film having an opening above the first conductive film; and
an upper layer conducive film electrically connected to the first conductive film through the opening, and
wherein the insulating film includes: a thick film portion located on the outside of the area where the plurality of mounting terminals are arranged in several rows in the staggered pattern; and
a thin film portion located in the area adjacent to the opening in the row direction of the staggered pattern with a thickness thinner than the thick film portion.

2. The wiring substrate according to claim 1, wherein the thick film portion is further formed in the area between the mounting terminals corresponding to neighboring lines.

3. The wiring substrate according to claim 1, wherein the thin film portion is further formed in the area between the mounting terminals corresponding to neighboring lines.

4. The wiring substrate according to claim 1, wherein the insulating film includes:
a first insulating film formed over the first conductive film;
a second insulating film formed over the first insulating film; and
a third insulating film formed over the second insulating film, and
wherein the second insulating film and the third insulating film are removed and the first insulating film remains in the thin film portions, and
the first insulating film, the second insulating film, and the third insulating film remain in the thick film portions.

5. The wiring substrate according to claim 4, wherein the line is covered by the first insulating film in the area where the line overlaps with the thin film portion.

6. The wiring substrate according to claim 4, wherein the mounting terminal further includes a second conductive film formed in a frame shape over the first conductive film so as to surround the opening,
the opening has a smaller width than the first conductive film so as to be located within the first conductive film in the row direction of the staggered pattern, and
the upper conductive film covers the opening and overlaps with the frame-shaped second conductive film.

7. The wiring substrate according to claim 4, wherein the opening has a larger width than the first conductive film in the row direction of the staggered pattern, and
the upper conductive film is formed larger than the first conductive film so as to cover the first conductive film.

8. The wiring substrate according to claim 7, wherein a pattern of a semiconductor layer is stacked on the first insulating film that covers the line in the thin film portion.

9. A display device comprising the wiring substrate according to claim 1, and a mounted component connected to the wiring substrate through an anisotropic conductive film.

10. A method of manufacturing a wiring substrate having a plurality of lines, and a plurality of mounting terminals each corresponding to respective one of the plurality of lines, the plurality of mounting terminals being arranged in several rows in a staggered pattern, the method comprising:
forming the lines and a first conductive film of the mounting terminals over a substrate;
forming an insulating film that covers the line and the first conductive film and has an opening above the first conductive film; and
forming an upper layer conducive film electrically connected to the first conductive film through the opening, and
wherein in the forming of the insulating film, both a thick film portion located on the outside of the area where the plurality of mounting terminals are arranged in several rows in the staggered pattern, and a thin film portion located in the area adjacent to the opening in the row direction of the staggered pattern with a thickness thinner than the thick film portion, are formed in the insulating film.

11. The method of manufacturing a wiring substrate according to claim 10, wherein the thick film portion is further formed in the area between the mounting terminals corresponding to neighboring lines.

12. The method of manufacturing a wiring substrate according to claim 10, wherein the thin film portion is further formed in the area between the mounting terminals corresponding to neighboring lines.

13. The method of manufacturing a wiring substrate according to claim 10, wherein the forming of the insulating film includes:
forming a first insulating film so as to cover the line and the first conductive film;
forming a second insulating film over the first insulating film;
forming a third insulating film over the second insulating film; and
forming the thin film portion and the opening in the insulating film after the forming of the third insulating film.

14. The method of manufacturing a wiring substrate according to claim 13, wherein the first insulating film, the second insulating film, and the third insulating film are removed in the opening,
the second insulating film and the third insulating film are removed in the thin film portion, and
the first insulating film, the second insulating film, and the third insulating film remain in the thick film portion.

15. The method of manufacturing a wiring substrate according to claim 13, further comprising:
forming a second conductive film between the first insulating film and the second insulating film,
wherein in the forming of the thin film portion and the opening, the opening and the thin film portion are formed using the second conductive film located in the thin film portion as a etching stopper, with the second conductive film being exposed in the thin film portion.

16. The method of manufacturing a wiring substrate according to claim 15, further comprising:
removing the second conductive film exposed in the thin film portion using the upper conductive film as a mask.

17. The method of manufacturing a wiring substrate according to claim 13, wherein in the forming of the second conductive film, the second conductive film is formed such that the second conductive film surrounds the opening,
in the forming of the thin film portion and the opening, the opening is formed such that the opening is located within the first conductive film in the row direction of the staggered pattern, and
in the forming of the upper conductive film, the upper conductive film is formed such that the upper conductive film overlaps with the second conductive film surrounding the opening so as to cover the opening.

18. The method of manufacturing a wiring substrate according to claim 13, wherein in the forming of the thin film portion and the opening, the opening is formed such that the opening has a larger width than the first conductive film in the row direction of the staggered pattern, and
in the forming of the upper conductive layer, the upper conductive layer is formed larger than the first conductive film so as to cover the first conductive film.

19. The method of manufacturing a wiring substrate according to claim 18, further comprising:
forming a semiconductor layer between the first insulating film and the second conductive film,
wherein in the forming of the thin film portion and the opening, the opening is formed so as to pierce through the second insulating film, the semiconductor layer, and the first insulating film with the first conductive film being exposed, and the thin film portion is formed in the area adjacent to the opening in the row direction of the staggered pattern so as to pierce through the second insulating film, with the second conductive film being exposed.
